(19) United States
(12) Patent Application Publication
(10) Pub. No.: US 2012/0203410 A1
(43) Pub. Date: Aug. 9, 2012

(54) SYSTEM FOR INDUCTIVELY CHARGING VEHICLES, COMPRISING AN ELECTRONIC POSITIONING AID

(75) Inventors: Mathias Wechlin, Kandern (DE); Mirko Heimburger, Offenburg (DE)

(73) Assignee: CONDUCTIX-WAMPFER AG, Weil am Rhein (DE)

(21) Appl. No.: 13/383,892

(22) PCT Filed: Jul. 13, 2010
(86) PCT No.: PCT/EP10/60027

§ 371 Date: Mar. 30, 2012

(30) Foreign Application Priority Data
Jul. 15, 2009 (DE) 102009033132.8

(51) Int. Cl. G05D 1/02; H05K 7/20; H05K 7/00

(52) U.S. Cl. 701/22; 361/679.01; 361/690; 361/695

(57) ABSTRACT

The main claim involves a system that ensures a self-guiding, electronic positioning of a secondary coil in a vehicle, without the aid of indicators or kinematic or mechanical aids, in relation to a primary coil that is fixed in a structure, in order to guarantee a transfer of energy with over 90% efficiency without the disadvantages of moving, frictional and elastic components in terms of energy consumption, functional safety and wear. To achieve this aim, the coil housing in the structure fulfills the role of an electronics housing, reflective element and cooling element thanks to the choice of material used, the surface and the inner supports and can thus be retrofitted, as a single installation on the structure in the form of an operation-ready complete package, to any flat base with an electric connection. The vehicle can be used both for transporting passengers and loads and can be steered by a vehicle driver or can be operated without a driver, for example for cleaning areas, for the protection of the countryside or for intralogistics

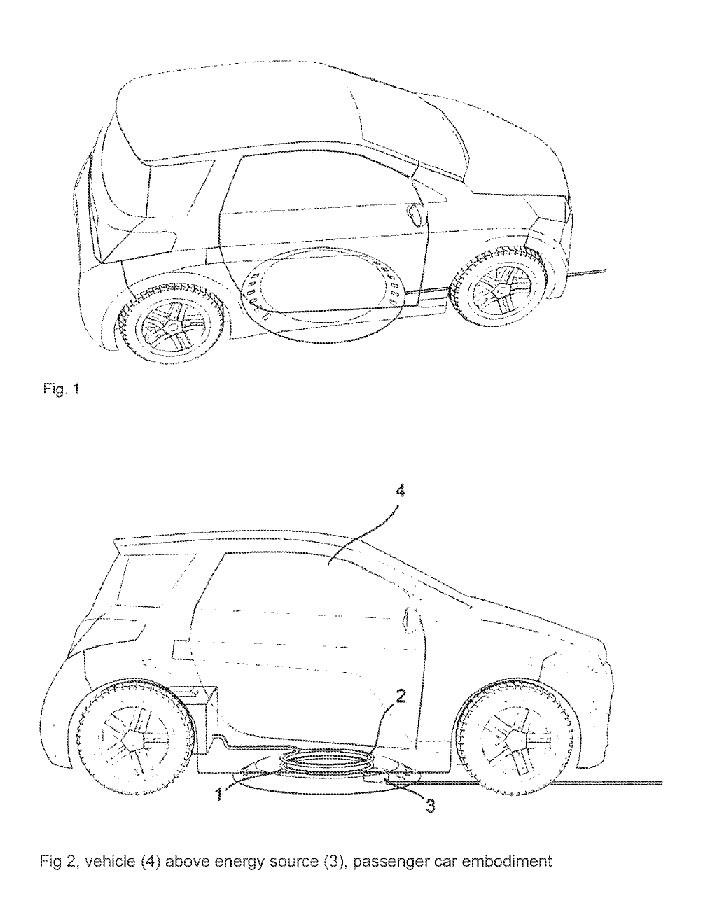

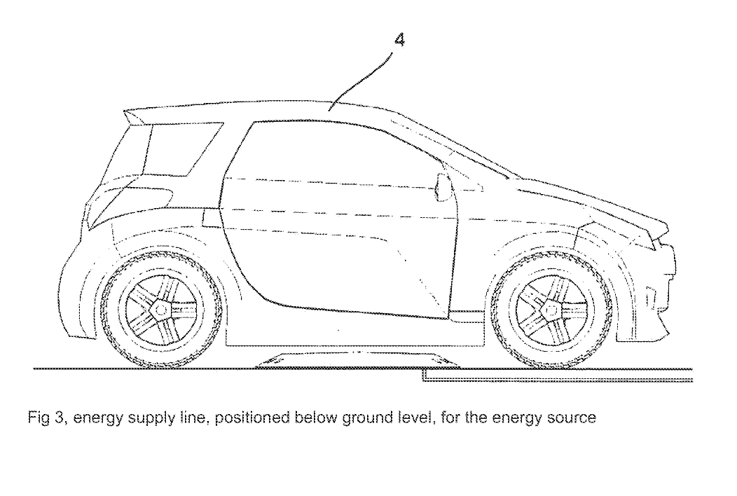

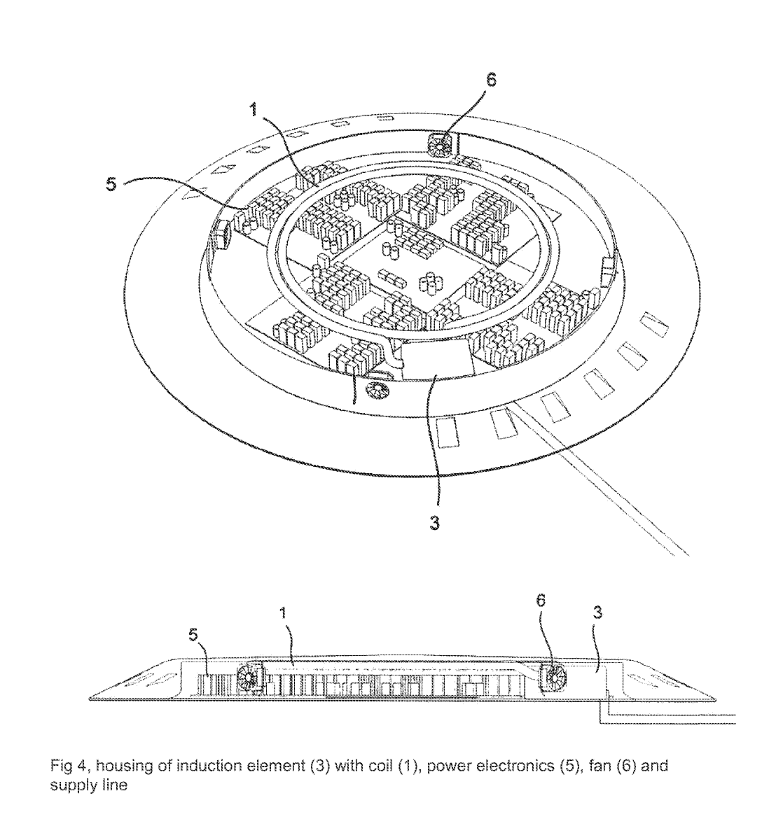

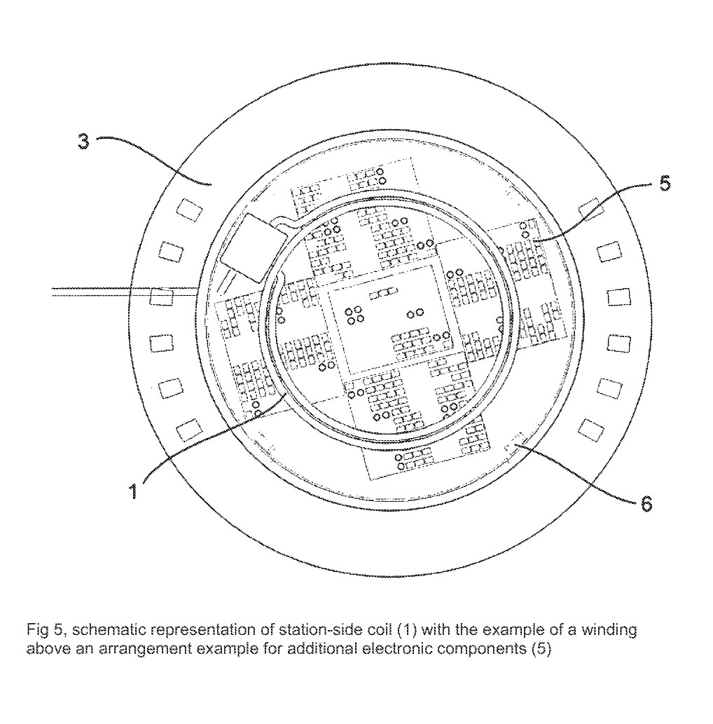

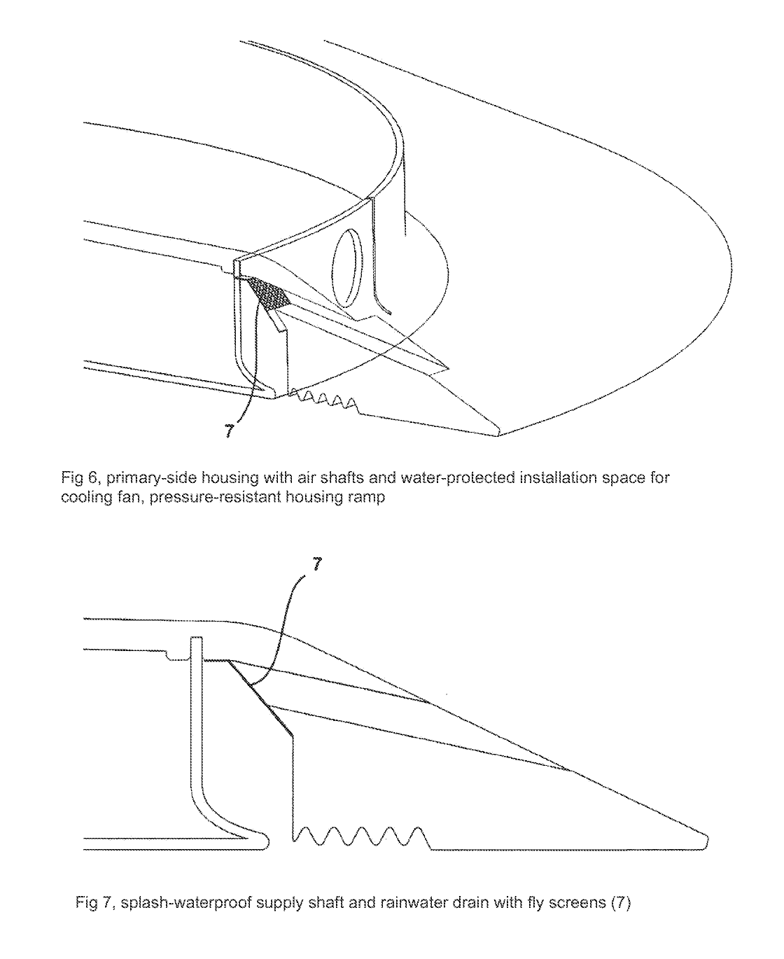

### PRIOR ART WITH SOURCES

Prior art to date is documented by (in order of filing date):

DE000004236286A1, H02J 7/00, Daimler, Oct. 28, 1992, coil lifting function via rigid lever, sensor-controlled kinematics of primary coil

JP000009017666AA, H01F 38/14, Toyoda, Jun. 28, 1995, mechanical positioning aid with wheel stoppers and displacement device

JP000008265992AA, H02J 17/00, Toyoda, Mar. 24, 1995, mechanical positioning aid, fine positioning with the assistance of probing charging current

U.S. Pat. No. 5,850,135, H02M 10/44, Sumitomo, Jan. 30, 1937, mechanical positioning aid on front end of vehicle, various kinematic forms of coil coupling, positioning via visual contact or wheel guidance, a wide variety of kinematics proposals. The IPC symbol H02M 10/44 could not be found in the 2009.01 version. It also could not be found in any other edition/version, cf. JP000009017666AA. All that was found is the examination class: H01M 10/46, storage batteries that are mechanically combined with the charging devices (charging circuits H02J 7/00). The documents cited include JP000058069404AA, filed by Denso on Oct. 21, 1981, but without any lateral or vertical positioning aid. Only a wheel stopper is shown.

JP002003079006AA, B60L 11/18, Yokohama, Sep. 3, 2001, fixed coil grooves with stoppers, as the only positioning aid, assumes fixed track width as a given.

JP002006345588AA, B60L 5/00, Matsushita, Jun. 7, 2005, kinematic positioning for coil coupling in an iterative method.

JP002007159359AA, B60L 11/18, Sumitomo, Dec. 8, 2005, positioning and communication in the vicinity via electromagnetic waves and kinematic positioning aid.

EP000001930203A1, B60L 11/18, Toyota, Aug. 31, 2006, (Sep. 29, 2005 in JP as JP002007097345AA) parking aid by means of video, in particular backup camera, initiation of the positioning process by user input to confirm the target surface, identification of the charging station and positioning by subjective video identification and an additional signal, moving aid for coil coupling, recognition not described in detail, of whether parked vehicle has a charging device, manual confirmation of the fine positioning. No operating state recognition.

DE102007033654A1, H02J 17/00, H01F 38/14, SEW, Jul. 17, 2007, coil lift initiated via wheel load, coupling by means of rigid lever, positioning via a groove.

The above publications and others disclose approaches for positioning assistance by means of active kinematics, passive positioning assistance via static wheel guidance elements in connection with rigid or kinematically positioned energy transfer units, or electronic positioning assistance using video signals and human video identification, as well as manual video selection, i.e., subjective locating, but do not describe any purely electronic, i.e. fully automatic coil locating with the option for fully automatic or semiautomatic positioning.

### Problem

Kinematics implies mechanical work, i.e. energy consumption, wear and functional risks. Fixed spacings of position transducers on the charging side imply a high standardization effort on the vehicle side. The optimal positioning results obtained in this way result in maximum energy transfer efficiency, but it is diminished by the energy input for the mechanical positioning aid and the high expense for production, installation and maintenance.

Video-based positioning aids, or prospecting or tracking by optical means, are dependent on suitable lighting conditions and the attention and interpretation capability of the driver. Insufficient illumination and backlighting lead to perception errors. Distance recognition and position determination via image processing is [sic; are] also not as precise as by means of radar.

Moreover, in order to identify coils of different providers or also to identify whether one coil in a series of several unoccupied ones is not ready for operation, the view of the driver through the window is indispensable and can thus not be replaced by viewing a monitor. Operating state displays or different providers cannot necessarily be distinguished on the video image.

In video identification, the driver must establish a connection between the concrete impression and the monitor image in order to select the coil in the environment of the vehicle displayed as a field on the monitor. The eyes shift back and forth between different windows around them and the monitor. This is cumbersome and error-prone.

### Solution

The problem of the invention according to claim 1 is a reduction of system and life-cycle costs, operating risks, human user error and technical malfunction-susceptibility by the most extensive possible avoidance of user intervention, mechanical work and friction, and additional or fault-susceptible sensory and driving assistance systems.

The electronic positioning aid allows a precise and universal manner of guidance, identical for all charging stations and vehicles, to a sufficient charging position. The coil housing installed above ground is used, due to its characteristic reflection properties and visible markings, for identification and simultaneously establishes a sufficiently small vertical distance from the secondary coil installed in the bottom of the vehicle.

### Advantages Achieved

The electronic positioning aid for inductive charging stations according to claim 1 provides more user convenience, functional safety and user certainty than manual charging with charging cables. It always operates reliably, independently of climatic conditions, contamination and driver discipline, knowledge and skill. Therefore the vehicle is connected to the public power network much more frequently. Both for charging and for energy feedback. This makes a widespread breakthrough of e-mobility into a mass phenomenon more probable and tends to secure the availability of vehicle batteries for compensating grid fluctuations during peak load periods.

The low-profile installation in the ground does not provide a target for vandalism or aesthetic objections. The shielding of energy and data transfer by the parked vehicle prevents misuse and tampering. Not only because the charging technology is largely inaccessible during the process, but also due to the low dissemination of protocols for induction-based communication. The inaccessibility and the forgoing of movable parts outside the vehicle also reduce the danger of injury.

### FURTHER CONFIGURATION OF THE INVENTION ACCORDING TO EMBODIMENT 2

An advantageous configuration of the invention is specified in Embodiment 2. The embodiment variant according to claim 2 makes it possible to use the higher precision and interference immunity of sensors based on radar. Radar sensors are being increasingly used in any case for distance control and obstacle detection in the near field, so that no additional costs need be incurred. They are being regularly used for parking aids due to increasing sensor fusion as well as component and functional integration, so that existing systems for semiautomatic parking can be utilized.

The sensor-based distance measurement and object locating, as well as the trajectory calculation and computer-based conversion of steering commands, can be used for sufficient positioning of the vehicle. The precision achieved by detecting the steering angle and the wheel revolution is sufficient for rough positioning. Additional indicators can be omitted.

Radar locating, in connection with the navigation system and voice input, is always faster than input on a touchscreen, since it automatically leads to the correct coil and the driver need only confirm the feedback prompt. The presettings of the user profile, together with the database entries, make it possible, for example, to always drive only to defined or preferred coils of a given provider or to shielded coils.

In a simplified embodiment, the parking process can also take place in the home garage for example, even without previous electronic coil locating, by means of manual rough positioning on the charging surface and activated fine positioning, preferably switching to coil wake-up mode, after a corresponding confirmation from the driver, when there is a shift to reverse, speed falls below walking speed or there is a sharp steering angle, and the vehicle is preferably semiautomatically precisely positioned, as in the operating steps for parking assistance.

This makes precise coil coupling accessible even to vehicles without radar sensors. A telematics function in the domestic area for accounting is also not necessary. This further lowers the system costs and will tend to be the rule for commuter vehicles in the introductory phase of electric mobility. The fixed coil can be installed aboveground as a retrofit kit, or underground with corresponding track marking. The latter facilitates floor cleaning and winter service. The underground variant is less suitable for radar locating in any case, and entails a larger coil distance.

### Further Configuration of the Invention According to Claim 4

By means of the configuration of the invention according to claim 4, the fixed coil housing with the ventilation slots becomes an unambiguously identifiable object, in which the surrounding ramp construction simultaneously provides sufficient strength for static and dynamic loads due to radar supporting surfaces of road vehicles, a high degree of integrity, sufficient radiation permeability for radar waves and cost-efficient manufacturing.

This externally visible ramp element completely covers the internal reflection rising edge. This makes the reflection pattern very difficult to imitate or tamper with. The charging disk has neither displays nor buttons or external connections, and is therefore a largely enclosed body with an attractive shape, slightly rounded on top. Internal LED lighting serves as a position lamp, an operating state display and lighting for the surroundings.

Due to the design of the invention according to claim 4, the bottom part of the stationary coil housing becomes a distance-compensating reflector via the peripheral concave rising edge and thus reflects a clear signal of higher strength than is otherwise customary in that position, which signal is fed back to the sensory system of the vehicle independently of the approach angle, the reflector returning a characteristic signal pattern that is undiminished within a large tolerance range, depending on the inclination between the vehicle and the installation position of the coil housing.

A clearly visible coil marking applied in several places provides information on the energy provider and makes the charging location distinctive. Visual identification by the driver cannot be replaced by image processing if electronic locating is not used, if any one of several unoccupied coils in a row could be chosen, or if the driver wants to use a coil from a defined provider or would like to avoid a coil with a negative operating state display. For this purpose, the coils are equipped with a marking similarly to the vehicles. It preferably consists of producer initials and a sequence of numbers.

### DESCRIPTION OF EMBODIMENTS WITH REFERENCE TO THE DRAWINGS

The vehicle (4) approaches the induction disk (3) from any side and automatically recognizes the charging coil on the ground in the automatic search mode of the radar, activated by a presetting, or in the manually activated search mode. In the presettings, the user can define, for example, automatic activation of the search mode in the vicinity of frequent destinations such as the work location or shopping location. Or he simply drives over the coil by visual approximation, without using radar locating.

A plausibility comparison via the navigation system continuously detects all charging discs in the near surroundings according to their database entries. Based on a simple driver command, the navigation system also leads the driver to the closest charging station or to the next unoccupied charging station, if the preferred telematics option with a corresponding return channel is present in the vehicle.

Following the plausibility comparison in the near vicinity, there are two options in case of an unoccupied charging station. Either the driver receives information via the navigation system regarding the operator and power data of the charging station. Or the driver is prompted to visually identify the desired charging station in case of a lack of a matching database entry or if there are several charging options available.

The coil (1) is approximately 70 mm above ground. The feed electronics (5) are located in the same housing underneath the coil body. The housing is enclosed except for the surface-water-protected slot for intake and exhaust air. The only external connection is the power cable. Housing fans (6) ensure air cooling.

The height of the coil housing is designed such that
the ground clearance of electric vehicles, rather small in any case, minus a typical spring travel for maximum charging, still allows sufficient free space,
the components of the feed electronics have space in the housing even in the worst case, when the maximum load is exceeded and the tire pressure falls below the minimum at the same time, and the vehicle rests on top of the coil housing and therefore a separate electronics housing, along with the corresponding wiring and installation expense, can be omitted.

At a distance of roughly 2 vehicle lengths, the near field radar automatically detects the characteristic reflector of the coil housing and offers the docking process to the driver by displaying the coil data on the screen, the covered reflector simultaneously guaranteeing functionality even if parts of it are covered by dirt or due to vandalism. The semiautomatic parking process is activated after confirmation.

Data regarding the charge state and billing are exchanged during the roughly 20 seconds for the approach. Fine positioning is accomplished using the existing algorithms of the parking aid in the ABS and the electromagnetic steering system, as well as by detecting wheel revolutions and the steering angle.

By drawing upon the probing charge current as a control element for fine positioning, it is possible to do without any other additional fine positioning aids such as proximity switches, magnetic field sensors or image processing systems. Since the charging process already starts in the rough capture range of the electromagnetic coil coupling, sufficient power transfer efficiency is utilized every second. In addition, the soft start of the charging increases the service life of the components involved, including the battery. The automatic self-regulating iteration turns the probing approach to the position with maximum coil congruence into a process barely perceptible to the driver that is finished within a few seconds.

The charging process begins immediately when the wheels stop. The automatically activated electric parking brake guarantees a secure charging operation independently of any sloping position or side inclination of the station surface.

Parking places with a charging station are approached as a matter of course only by vehicles that want to charge or offer feed back energy. Only appropriate electrical vehicles are authorized to use such parking spaces. The driver automatically consents to the terms and conditions of business by his usage.

A station-side query of whether to charge is unnecessary since the vehicle-side coil (2) necessarily wakes up the station-side coil (1) during the fine positioning, and charging or feedback begins, depending on the condition of the vehicle battery and/or the available capacities in the public grid.

Without this automatic activation, valuable time windows for charging the vehicle storage batteries with excess grid power or for urgently required feedback into the public grid would be lost. Overall, only automatic charging or feedback can guarantee high availability of range for the electrical vehicles and peak load compensation in the public grid.

Fundamental algorithms ensure that
preset minimum charge levels are not violated during the automatic feedback
remaining charge capacity above a maximum amount set by the user is used only when the most economical night power rates are available
depending on the other presettings, maximum charging is available on days and at times of day preset by the user
depending on the other presettings, maximum feedback takes place on days and at times of day preset by the user
a sufficient charge for the travel destination is available for the destination input and departure time input by the user when parking

In another embodiment, the multimedia interface of the navigation system offers extra services such as automatic logging of charging locations, duration of charging or feedback, battery capacity before and after the charging process, or statistics on the number, frequency and spatial distribution of the charge stations used, as well as additional similar services. Via an Internet connection, the telematics service of the navigation system can transfer the data to a user e-mail box or to a protected area of a user portal. This makes it substantially easier for the driver to check power bills from the energy suppliers or determine the suitable rate for his user profile.

### LIST OF REFERENCE NUMBERS

1 Station-side primary coil
2 Vehicle-side secondary coil
3 Station-side coil housing
4 Vehicle
5 Electrical and electronic systems
6 Fan
7 Fly screen

1. Electronic positioning aid for electric vehicles in the near vicinity of inductive charging stations
wherein
sensors present in the vehicle or optionally provided therein, based on radar, laser, lidar, ultrasound, infrared, satellite or induction and the parking aids based thereon are additionally used to recognize inductive charging stations in the near vicinity fully automatically based on the station-side coil housing or the internal coil technology, without visual environment representation, without manual user input and without additional station-side reflectors, and to position the vehicle in the computer-assisted parking operation with the coil in the bottom of the vehicle sufficiently accurately above the station-side coil, without the two coils having to be brought into a more precise or closer superimposition with additional moving or lifting devices.

2. Positioning aid according to claim 1,
wherein
the preferred environment detection is near-field radar.

3. Positioning aid according to claim 1, wherein
the presence of metallic objects on the coil housing is ruled out, preferably via near-field radar, and interference-free charging is thus ensured.

4. Ground-side coil housing for an inductive charging station,
wherein
the station-side coil housing preferably simultaneously serves as a highly characteristic reflector for the vehicle-side scanning sensors, the circumferential concave rising edge constituting a reflector for the radar signal in a wide range of distances and simultaneously for a wide range of approach angles, due to the circular base surface.

5. Ground-side coil housing according to claim 4,
wherein
the coil housing roof preferably has an electromagnetic radiation permeability as high as possible for an interference-free coupling of the coils, and the coil housing wall preferably has an electromagnetic radiation permeability as low as possible for an optimally good radar reflection.

6. Ground-side coil housing according to claim 4,
wherein
the entire visible housing surface can be manufactured from a single plastic composite material with a high electromagnetic transmission value by a fully automatic injection-compression or injection-molding process without undercuts, off-tool and in one piece.

7. Ground-side coil housing according to claim 4,
wherein
two separating tabs projecting from the underside of the upper housing part preferably prevent a recirculation of the exiting warm air and simultaneously serve as a fail-safe positioning pattern for the assembly of the upper housing part and the base part.

8. Ground-side coil housing according to claim 4, wherein
the coil housing is preferably furnished on the circumferential ramp with 4 characteristic surfaces offset by 90°.

9. Ground-side coil housing according to claim 4,
wherein
the base part together with the circumferential rising edge are produced off-tool from a single flat metal sheet by a fully automatic stamp-bending and deep-drawing process together with the positioning fold for the positioning template.

10. Ground-side coil housing according to claim 4,
wherein
due to the circumferential rising edge, water penetrating into the circumferential labyrinth system, over a wide tolerance range of inclined positions, preferably always flows off on the opposite side before it can penetrate via the air inlets into the interior of the housing.

11. Ground-side coil housing according to claim 4,
wherein
the rising inclined air intake slots in the upper housing part protect the electronics in the housing from spray water and surface water over a wide tolerance range of inclined positions, and water penetrating up to the rising edge can flow off via holes around the lower edge of the concave rising edge and flow off via the cavity below the base part.

12. Ground-side coil housing according to claim 4,
wherein
the all-metal base part preferably also provides a sufficiently large surface for convection cooling.

13. Ground-side coil housing according to claim 4,
wherein
an LED lighting unit with a central light source in various primary colors simultaneously, via an optical fiber running circumferentially in the area behind the rising edge behind the ventilation slots, indicates the operating state, serves as a position light and provides for lighting of the surroundings.

14. Ground-side coil housing according to claim 4, wherein
the housing preferably integrates the feed-in or feed-back electronics, in addition to the coil.

15. Ground-side coil housing according to claim 4,
wherein
fly screens in the air-intake slots preferably protect the electronics from flying and crawling insects and prevent the ingress of floating materials or large accumulations of dirty water, the fly screens being easily interchangeable and easy to clean.

16. Ground-side coil housing according to claim 4,
wherein
the coil housing is preferably air-cooled via crossflow ventilation.

17. Ground-side coil housing according to claim 4,
wherein
the temperature control unit of the fans preferably interrupts the charging process in case of overheating or, in case of excessive direct solar irradiation with corresponding heating, only allows the charging process to start offset in time or to a lesser extent, when the vehicle shadow has permitted sufficient cooling to occur.

18. Positioning aid according to claim 1, wherein
preferably, using telematic service, there is a plausibility check of the localization of the charging station via the database of the regularly updated or self-learning navigation system present in the vehicle or optionally provided therein,
whereupon the navigation system displays data such as the operator and power capacity of the charging station.

19. Positioning aid according to claim 1,
wherein
in case of the lack of a matching database entry for the coil, and also in case of a number of unoccupied coils located close to one another, or if the driver wishes to select the coil of a given provider in visual range and various providers operate in the immediate vicinity, the system prompts a visual identification based on the coil characteristic.

20. Positioning aid according to claim 1,
wherein
the coil characteristic is preferably faded in via a heads-up display and the input preferably takes place via voice input, wherein the coil with the easiest approach is preferably displayed as a highlighted suggestion in a list of available coil characteristics.

21. Positioning aid according to claim 1, wherein
the driver can confirm the suggestion or select an alternative coil by inputting the list entry number.

22. Positioning aid according to claim 1,
wherein
the parking aid present in the vehicle or optionally provided therein, expanded by the locating aid for the charging coil, takes over the guidance of the vehicle to the charging location depending on the installation location of the receiver coil on the bottom of the vehicle, wherein the station-side charging coil is preferably located in the center of the parking space and the vehicle-side coil is preferably located centrally on the bottom of the vehicle.

23. Positioning aid according to claim 1,
wherein
preferably, as is common in semiautomatic parking aids, the driver initiates the next parking step by actuating the braking and accelerator pedals or, by gripping the steering wheel, can interrupt the process at any point or activate a fully automatic autopilot for the positioning on the coil.

24. Positioning aid according to claim 1,
wherein
in the fine-positioning area a few centimeters in size or in an appropriately adjusted capture range, the vehicle-side coil preferably wakes up the station-side coil with an electromagnetic pulse and simultaneously an inductive communication between the two coils starts, superimposed on the inductive energy transmission, an exchange preferably always being obligatorily initiated as part of the user's presettings, without intervention by the user and without a station-side query.

25. Positioning aid according to claim 1,
wherein
the driver is preferably identified for authorization and accounting of the charging and feedback process via his individual vehicle key, the latter also preferably storing his other personal settings such as the preset minimum values for charging and feeding back, or seat and air-conditioning settings.

26. Positioning aid according to claim 1,
wherein
the authorizations for the individual vehicle key are preferably activated via the online portal of the vehicle-side telematics service in connection with the offerings of the energy supply companies.

27. Positioning aid according to claim 1,
wherein
in the fine positioning area a few centimeters in size, the charging process preferably begins with a probing charge, wherein the parking aid preferably only draws upon the ultimate strength of the charging current as an additional control variable alongside the already existing, still prioritized distance warning devices, without additional magnetic field sensors, and brings about an exact overlapping of the two coils within a few seconds on the shortest possible paths by iteratively offset driving forward, backward and laterally.

28. Positioning aid according to claim 1,
wherein
in case of a negative plausibility comparison after the charging station has been located, the self-learning navigation system automatically reports the data acquired in the charging process for the not yet recorded charging station via a return channel to the telematics service, preferably independent of vehicle manufacturers, whereupon the new charging station is documented from then on for all users of the service via the central online portal.

29. Positioning aid according to claim 1,
wherein
the exact charging location is automatically documented based on satellite coordinates, preferably via the navigation system, and key data such as charging time, charge state before and after charging, duration of charging and the like are made available, preferably inductively, by the onboard computer in the vehicle or optionally provided therein, whereby the charging data can be made available to the user permanently and automatically, preferably via an inductive return channel or via a vehicle manufacturer-independent telematics service independent of vehicle manufacturers, GSM, an Internet connection or a data interface in the vehicle such as USB.

30. Positioning aid according to claim 1,
wherein
feedback processes, in which excess energy is transmitted from the vehicle-side accumulator to the grid in peak demand times, can also be documented, preferably conveniently and reliably, via the same navigation system with the preferably manufacturer-independent telematics service.
